(19) United States
(12) Patent Application Publication
(10) Pub. No.: US 2026/0005705 A1
(43) Pub. Date: Jan. 1, 2026

(54) Adaptive Cache Synchronization System for Federated Large Codeword Models

(71) Applicant: AtomBeam Technologies Inc., Moraga, CA (US)

(72) Inventor: Brian Galvin, Silverdale, WA (US)

(21) Appl. No.: 19/332,563

(22) Filed: Sep. 18, 2025

Related U.S. Application Data
(63) Continuation-in-part of application No. 19/242,953, filed on Jun. 18, 2025.
Application No. 19/242,953 is a continuation-in-part of application No. 19/088,978, filed on Mar. 24, 2025.
Application No. 19/088,978 is a continuation of application No. 18/909,976, filed on Oct. 9, 2024, now Pat. No. 12,261,631.
Application No. 18/909,976 is a continuation-in-part of application No. 18/736,498, filed on Jun. 6, 2024.
(63) Continuation-in-part of application No. 19/017,639, filed on Jan. 11, 2025, now Pat. No. 12,425,044.
Application No. 19/017,639 is a continuation of application No. 18/919,394, filed on Oct. 17, 2024, now Pat. No. 12,231,151.
Application No. 18/919,394 is a continuation-in-part of application No. 18/898,608, filed on Sep. 26, 2024, now Pat. No. 12,314,839.
Application No. 18/898,608 is a continuation-in-part of application No. 18/890,748, filed on Sep. 19, 2024, now Pat. No. 12,373,739.
(60) Provisional application No. 63/651,359, filed on May 23, 2024.

(51) Int. Cl. H03M 7/30; G06N 20/00

(52) U.S. Cl. CPC H03M 7/3059; G06N 20/00; H03M 7/6005

(57) ABSTRACT

A system and method is provided for adaptive sharing of cached results in a distributed machine learning environment. The system receives compressed representations of input data from multiple devices and processes them through a model to generate responses. These responses are stored in both local caches and a shared global cache. Each response is evaluated for reuse and classified for privacy, allowing some to be shared widely, some only with select groups, and others to remain private. Usage patterns from different devices are combined to train models that guide which cached responses should be retained or synchronized. Synchronization is managed adaptively, adjusting when and how information is shared depending on network conditions, utility, and privacy budgets. Before sharing, privacy safeguards such as encryption or differential privacy are applied, and entries are distributed through a coordinating system that ensures consistency and avoids duplication across devices.

### CROSS-REFERENCE TO RELATED APPLICATIONS

Priority is claimed in the application data sheet to the following patents or patent applications, each of which is expressly incorporated herein by reference in its entirety:
Ser. No. 19/242,953
Ser. No. 19/088,978
Ser. No. 18/909,976
Ser. No. 18/736,498
63/651,359
Ser. No. 19/017,639
Ser. No. 18/919,394
Ser. No. 18/898,608
Ser. No. 18/890,748

### BACKGROUND OF THE INVENTION

### Field of the Art

The present invention relates to the field of distributed machine learning, and more specifically to systems and methods for privacy-preserving caching and adaptive synchronization of compressed or encrypted model representations in federated learning architectures.

### Discussion of the State of the Art

Distributed machine learning systems have increasingly adopted federated learning architectures to enable collaborative model training without requiring centralized access to sensitive data. These architectures typically allow edge devices to compute localized model updates, which are then aggregated into a global model. While this structure preserves data locality and can enforce basic privacy constraints, it often results in high bandwidth usage and redundant computation, especially when similar queries are repeatedly processed across different nodes.

Recent approaches have attempted to address this inefficiency by integrating hierarchical caching systems within edge-based learning environments. These caching strategies can store previously generated responses or intermediate representations, reducing the need to invoke full model inference for each new input. However, such caching systems generally function in isolation or rely on static synchronization rules, lacking the ability to adapt to network variability, privacy constraints, or changing model behavior. Moreover, conventional cache-sharing mechanisms fail to incorporate fine-grained privacy classification or differential privacy protections when distributing cache contents across nodes, increasing the risk of inadvertent information disclosure.

At the same time, systems that operate on compressed or encrypted representations, such as codewords derived from entropy-encoded latent vectors, offer promising avenues for improving the efficiency and security of federated learning. Nevertheless, these systems often treat the learning core and the caching infrastructure as distinct components, without a unified mechanism for governing cache synchronization in a privacy-aware and performance-sensitive manner.

What is needed is an adaptive cache synchronization system for federated codeword-based machine learning architectures that enables selective, privacy-preserving sharing of cached responses across distributed nodes, while dynamically optimizing synchronization policies based on privacy classification, network conditions, and model utility metrics.

### SUMMARY OF THE INVENTION

Accordingly, the inventor has conceived and reduced to practice an adaptive cache synchronization system for federated large codeword model architectures. The system enables selective sharing of cached machine learning outputs across distributed nodes while maintaining strict privacy guarantees and optimizing resource usage. By integrating privacy-aware decision logic with federated cache learning, bandwidth-sensitive synchronization control, and secure aggregation mechanisms, the system improves both efficiency and privacy in distributed machine learning deployments that operate on compressed codeword representations.

In an embodiment, a computer system is configured to receive codeword-derived representations from a plurality of distributed nodes. These representations are generated by upstream compression and transformation pipelines that may include variational autoencoders, entropy coders, or other encoding mechanisms. The system processes the codeword-derived representations through a machine learning model to produce one or more responses, and stores these responses in a hierarchical cache structure comprising both a local cache associated with the receiving node and a global cache accessible across multiple nodes. Each cached response is evaluated for its potential reuse and for sharing eligibility, taking into account content characteristics, usage history, and privacy classification criteria. A privacy-aware cache selector determines a classification level for each cached response, such as public, group-private, or fully-private, based on contextual metadata and policy rules. Usage metrics collected from the distributed nodes are aggregated into a federated cache learning system, which generates optimization models to guide cache retention and sharing policies across the network. An adaptive synchronization controller dynamically adjusts the timing, frequency, and scope of cache synchronization operations in response to network conditions, model performance metrics, and privacy budget status. Before cached responses are shared, a privacy mechanism is applied, which may include differential privacy techniques, homomorphic encryption, or removal of identifying elements. A federated cache aggregator coordinates the distribution of selected responses to participating nodes, resolving content conflicts, deduplicating similar entries, and maintaining version consistency.

In an aspect of an embodiment, the privacy-aware cache selector assigns cached responses to a tiered structure that includes a public tier, a group-private tier, and a fully-private tier, each reflecting a different level of sharing eligibility and privacy sensitivity.

In an aspect of an embodiment, group-private responses are encrypted using homomorphic encryption before being distributed to a designated set of authorized nodes.

In an aspect of an embodiment, the federated cache learning system uses a federated averaging algorithm to compute cache optimization models based on anonymized usage statistics contributed by multiple nodes, without accessing the underlying response content.

In an aspect of an embodiment, the adaptive synchronization controller employs delta synchronization techniques that reduce transmission overhead by sending only changed portions of cached responses rather than entire entries.

In an aspect of an embodiment, the privacy mechanism includes a differential privacy engine that introduces calibrated noise to cache access statistics before those statistics are aggregated across the network.

In an aspect of an embodiment, the system enforces k-anonymity by restricting cache synchronization operations to responses that have been independently associated with at least k distinct users.

In an aspect of an embodiment, the federated cache aggregator maintains a distributed hash table that maps semantic identifiers to cache entries, enabling efficient discovery and targeted synchronization.

In an aspect of an embodiment, the federated cache aggregator performs semantic deduplication by identifying functionally equivalent responses through vector similarity analysis or contextual alignment of prompts, thereby minimizing redundant storage and transmission across the network.

### BRIEF DESCRIPTION OF THE DRAWING FIGURES

FIG. 1 is a block diagram illustrating an adaptive cache synchronization system for federated large codeword models, showing core components for federated learning, hierarchical caching, privacy analysis, synchronization, and aggregation.

FIG. 2 is a flow diagram illustrating a cache synchronization lifecycle in which responses are generated at edge devices, classified for privacy, synchronized across a network, stored in global caches, and reused by other devices.

FIG. 3 is a flow diagram illustrating privacy-aware cache selection and classification where cached responses are scored, assigned to tiers, encrypted or anonymized if necessary, and either shared or retained locally.

FIG. 4 is a flow diagram illustrating federated cache learning and optimization in which anonymized usage statistics are collected from devices, aggregated and trained into cache optimization models, and redistributed to improve local caching policies.

FIG. 5 is a flow diagram illustrating adaptive synchronization scheduling where runtime conditions are monitored, cache entries prioritized, privacy budgets checked, payloads prepared, and synchronization windows scheduled for distribution.

FIG. 6 is a flow diagram illustrating aggregator conflict resolution and deduplication in which responses from multiple nodes are compared, functionally equivalent entries are merged, version conflicts are resolved, and global caches are updated.

FIG. 7 illustrates an exemplary computing environment on which an embodiment described herein may be implemented.

### DETAILED DESCRIPTION OF THE INVENTION

The inventor has conceived and reduced to practice a system and method for adaptive cache synchronization in federated machine learning environments that operate on compressed or encrypted data representations. The system enables distributed computing nodes to share cached model responses selectively, based on their relevance, privacy characteristics, and synchronization priority. This improves computational efficiency, reduces bandwidth consumption, and preserves privacy under configurable policy constraints across a network of cooperating devices.

In an embodiment, input data is first transformed at the node level using a compression pipeline. This pipeline may include semantic segmentation of the input, variational encoding into a latent space, and transformation of the latent distribution into a form optimized for entropy coding. A dyadic transformation may be applied to restructure the distribution for efficient encoding, followed by lossless or lossy entropy compression such as Huffman encoding. The output of this pipeline may be encrypted using homomorphic encryption or similar privacy-preserving techniques, producing codeword-derived representations that are both compact and secure.

In an embodiment, the homomorphic encryption used for securing codeword-derived representations may include lattice-based schemes such as, for example, CKKS or BGV implementations, which enable arithmetic operations on encrypted vectors. In other embodiments, partially homomorphic schemes may be used when only limited operations, such as addition or multiplication, are required. The compression stage may further employ entropy coders such as arithmetic coding or range coding in place of Huffman encoding. These approaches are described as non-limiting examples to illustrate possible configurations of the compression pipeline, and other compression and encryption methods may likewise be employed.

These representations are transmitted from edge nodes to a computing system that executes a machine learning model trained to operate on such inputs. The model may be a transformer, latent transformer, or other architecture capable of processing codewords or latent vectors directly. Upon inference, the system generates a response, which may itself be composed of codewords, abstract embeddings, or task-specific outputs such as answers, predictions, or control signals.

Each response is stored in a hierarchical cache architecture. A local cache may reside on the device generating the output and is used for short-term or high-frequency reuse. A global cache spans multiple nodes and enables cross-device retrieval of previously generated responses, allowing devices to benefit from computations performed elsewhere. Both caches may store additional metadata such as prompt context, timestamps, model versioning, and relevance scores. To determine whether and how a response should be shared across the network, the system includes a privacy-aware cache selector. This component evaluates the sensitivity of each cached response by examining its content, the nature of the input prompt, the identity or attributes of the requesting user, and the applicable privacy policy. Responses may be classified into privacy tiers such as public, group-private, or fully-private. This classification determines the allowable scope of synchronization.

Public responses may be shared freely across the network, while group-private responses may be encrypted and distributed only to a limited set of authorized devices. Fully-private responses are retained only on the originating node. The selector may dynamically reclassify cached entries as new access patterns emerge or policy thresholds change.

To further enforce privacy constraints, a cache privacy analyzer evaluates cache access behavior and sharing operations. This analyzer may enforce a per-device privacy budget, which decrements as responses are shared based on the estimated information revealed. It may also introduce noise into reported access statistics using differential privacy techniques and apply k-anonymity checks to ensure that shared responses cannot be linked to any individual user with high confidence. In some cases, the analyzer may automatically redact sensitive entities or perform linguistic or structural scrubbing on the cached content before it is made eligible for synchronization.

A synchronization controller governs when, how often, and to what extent cached entries are synchronized across nodes. This controller may evaluate a variety of runtime conditions, including current network bandwidth, cache hit and miss rates, device capacity constraints, and observed model drift. It dynamically adjusts synchronization policies based on these factors. During periods of limited bandwidth or elevated privacy risk, synchronization may be deferred, throttled, or limited to high-priority responses. To further reduce overhead, the system may implement delta synchronization strategies, transmitting only changed portions of cache entries rather than full duplicates.

In an embodiment, an adaptive synchronization controller may compute a synchronization priority score for each cache entry. The score may be based on a weighted combination of factors such as reuse frequency, privacy budget consumption, estimated network overhead, and relevance score associated with the cached response. For example, an entry that has been reused more than a threshold number of times and is classified as public may be prioritized for immediate synchronization, whereas a fully-private entry with low reuse frequency may be deferred. In another embodiment, the synchronization cadence may be dynamically adjusted using bandwidth monitoring agents that sample real-time throughput on the communication link. These descriptions are provided as non-limiting examples of how adaptive synchronization policies may be implemented.

The system also includes a federated cache learning mechanism that aggregates anonymized cache usage patterns from distributed nodes. This mechanism collects metrics such as response reuse frequency, prompt similarity distributions, and observed model utility gains associated with cache hits. These metrics are aggregated using privacy-preserving learning techniques, such as federated averaging, to train optimization models that predict which types of responses are likely to offer the most value if replicated elsewhere. These optimization models are then shared back to the edge devices, where they inform local caching and retention strategies.

In an embodiment, the federated cache learning system may employ federated averaging across distributed nodes, where each node trains a local prediction model using anonymized cache metadata. Local model updates may include gradients or parameter deltas derived from decision tree classifiers, recurrent neural networks, or other lightweight learning architectures. These updates may be aggregated without revealing underlying cache content. The resulting optimization model may be validated against synthetic workloads to estimate prediction accuracy, latency savings, and privacy preservation. The system may then distribute model updates to edge devices with digital signatures to maintain provenance and prevent tampering. These examples are illustrative and not limiting to any particular machine learning architecture.

Cache entries selected for sharing are distributed via a federated cache aggregator. This component indexes cache entries across the network using distributed data structures such as hash tables or graph-based lookup schemes. The aggregator performs semantic deduplication to identify responses that are functionally equivalent but syntactically distinct, using vector similarity or prompt alignment techniques to collapse redundant entries. It also manages version control, ensuring that updated or revised responses are accurately propagated without conflict. In addition, the aggregator may enforce fairness constraints so that no single node disproportionately consumes network cache resources or storage quotas.

In an embodiment, the federated cache aggregator may further implement eviction and replacement strategies to maintain storage efficiency. For example, least-recently used (LRU) policies may be employed for short-term storage tiers, while least-frequently used (LFU) or utility-based eviction may be applied for persistent tiers. In another embodiment, semantic deduplication may be performed using cosine similarity of vector embeddings or by applying clustering algorithms such as k-means or hierarchical clustering to group functionally equivalent responses. These approaches are presented as non-limiting examples of how cache state may be managed to balance efficiency, redundancy elimination, and fairness.

The overall architecture may be implemented across cloud, edge, or hybrid deployments. Nodes may be mobile devices, IoT sensors, server clusters, or autonomous agents, and the components of the system may be realized in hardware, software, or firmware. The system may operate continuously, on a periodic schedule, or opportunistically in response to event triggers or environmental conditions. In an embodiment, the system may be implemented on heterogeneous hardware environments. For example, encryption operations may be performed within trusted execution environments such as Intel SGX enclaves or ARM TrustZone partitions, while inference and cache management may be accelerated using GPUs, TPUs, or FPGAs. Edge devices such as smartphones or IoT gateways may integrate lightweight cache controllers optimized for constrained memory environments. These hardware descriptions are provided as non-limiting examples to demonstrate possible implementations that tie the disclosed methods to specific computing environments.

By integrating privacy-aware cache selection, dynamic synchronization control, federated learning of caching strategies, and secure aggregation protocols, the system enables efficient reuse of machine learning responses in distributed environments. It reduces unnecessary computation, adapts to changing privacy and network conditions, and maintains consistency and privacy across diverse infrastructure. This combination of features provides a flexible and scalable framework for deploying federated learning systems that rely on compressed or encrypted representations.

In an embodiment, the system may be deployed in a healthcare environment where multiple hospital systems collaborate to train diagnostic models on encrypted patient data. Edge devices located within hospital networks may cache model responses to frequently seen conditions such as pneumonia classifications or tumor segmentations. The adaptive cache synchronization system enables selective sharing of generalized responses-such as common visual patterns-across participating institutions, while keeping patient-specific responses fully isolated. The privacy-aware cache selector may prevent synchronization of any entries containing identifiers, and the cache privacy analyzer may enforce k-anonymity before enabling cross-hospital sharing. The result is improved diagnostic performance across the federation without compromising patient confidentiality.

In another embodiment, the system may be used within a fleet of autonomous vehicles. Each vehicle may include onboard sensors that capture environmental context, which is compressed into codeword-derived representations and processed through a local model for navigation decisions. Responses associated with rare but high-risk driving scenarios, such as sudden lane obstruction or erratic pedestrian movement, may be cached locally and selectively synchronized to other vehicles in the fleet. The adaptive synchronization controller may prioritize synchronization during periods of low network congestion, and the federated cache aggregator may identify functionally equivalent responses generated by different vehicles to avoid redundant storage. Privacy policies may restrict synchronization to vehicles operating within the same jurisdiction or geographic zone.

In an embodiment involving large language model (LLM) deployment at the edge, the system may be used to accelerate user interactions with assistant agents. Devices such as smartphones or AR headsets may cache responses to common or semantically similar prompts, such as local directions, restaurant recommendations, or frequently asked questions. The federated cache learning system may identify which responses exhibit high cross-user utility, enabling the global cache to distribute them to other devices operating in the same region or under the same service context. Fully-private responses, such as those involving user-specific calendar events or contacts, may remain unshared under the control of the privacy-aware cache selector. Differential privacy mechanisms may be used to obfuscate access patterns across the network, further preserving user privacy.

In a smart grid environment, the system may be applied to edge controllers managing energy distribution in residential and industrial zones. Each node may generate predictive responses based on consumption patterns, weather conditions, or scheduled operations. When certain conditions recur—such as peak load scenarios—the cached response may be reused to preemptively adjust demand or activate secondary power sources. The federated cache aggregator may prioritize synchronization of these high-impact responses, while the cache privacy analyzer ensures that building-level consumption patterns are not inadvertently disclosed. Synchronization timing may be adjusted by the controller to align with grid stability priorities and available communication bandwidth.

These embodiments illustrate how the described system can adapt to a range of real-world contexts, each with varying privacy constraints, synchronization requirements, and model workloads. Whether deployed in safety-critical environments, regulated industries, or consumer-facing platforms, the system supports efficient reuse of machine learning outputs while respecting operational, privacy, and resource constraints.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in the one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only, and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Definitions

As used herein, “adaptive cache synchronization system” refers to a computer-implemented system configured to manage the sharing of cached responses across distributed nodes in a federated learning environment while dynamically adjusting synchronization policies based on privacy, bandwidth, and utility considerations.

As used herein, “federated learning” refers to distributed training or inference in which multiple devices contribute model updates or usage data without requiring centralized access to raw input data.

As used herein, “codeword-derived representation” refers to a compressed or transformed form of input data generated through encoding pipelines such as variational autoencoders, entropy coders, or encryption schemes, which may be suitable for direct processing by machine learning models.

As used herein, “hierarchical cache” refers to a multi-tiered memory structure including a local cache maintained at an edge device and a global cache accessible across multiple devices.

As used herein, “privacy-aware cache selector” refers to a subsystem configured to evaluate cached responses and assign them to privacy tiers such as public, group-private, or fully-private.

As used herein, “federated cache learning system” refers to a subsystem configured to aggregate anonymized usage statistics from distributed devices and train optimization models that inform caching and synchronization policies.

As used herein, “adaptive synchronization controller” refers to a subsystem configured to adjust timing, frequency, and scope of cache synchronization operations based on observed runtime conditions and policy constraints.

As used herein, “cache privacy analyzer” refers to a subsystem configured to enforce privacy protections, including differential privacy, k-anonymity, and privacy budgets, when cached responses are considered for synchronization.

As used herein, “federated cache aggregator” refers to a subsystem configured to coordinate distribution of cache entries across devices, perform conflict resolution, manage version consistency, and conduct semantic deduplication.

As used herein, “privacy budget” refers to a numerical representation of allowable information disclosure associated with cache sharing operations, which may decrement as synchronization occurs.

As used herein, “differential privacy” refers to a class of techniques that introduce calibrated noise into data or statistics to prevent inference of individual user information.

As used herein, “delta synchronization” refers to a synchronization technique in which only changed portions of cached entries are transmitted, rather than complete entries.

As used herein, “semantic deduplication” refers to a process of identifying and merging functionally equivalent responses that may differ syntactically but convey similar meaning or output utility.

### Foundational Architecture

U.S. patent application Ser. Nos. 19/017,639 and 19/242,953 are hereby incorporated by reference in their entirety. While the complete disclosures of those applications remain part of the record, the following summary provides an overview of certain architectural elements that are relevant to understanding the systems and methods described herein. This summary is provided solely to offer technical context and does not limit or redefine the scope of the incorporated disclosures or the present application.

The previously disclosed architecture includes a large codeword model designed to support efficient and privacy-preserving deep learning in distributed environments. Source data such as text, images, audio, or sensor streams may be segmented into semantically meaningful units referred to as sourceblocks. These sourceblocks may be mapped to codewords using a codebook, which in various embodiments may be constructed using Huffman coding, arithmetic coding, or encoder-based quantization methods. The resulting codewords serve as symbolic, compressed representations of the original data and may be used as inputs to downstream machine learning models.

Before model processing, data may be transformed using a homomorphic compression and encryption pipeline. In some embodiments, a variational autoencoder is used to project the input into a latent space. The latent vectors may then be processed through a dyadic transformation to produce a distribution optimized for entropy encoding. A transformation matrix generator may produce a stochastic mapping that reshapes the distribution while preserving mathematical structure. A stream generator may divide the transformed output into a primary data stream and a secondary stream that encodes transformation information. These streams may be compressed using Huffman encoding, and in some cases interleaved and further processed by a security subsystem using randomized encoding techniques. In certain implementations, the resulting data may retain homomorphic properties, thereby enabling computation on encrypted representations without requiring decryption.

The model architecture supports multiple learning cores. In some cases, a conventional transformer may be used, incorporating embedding layers, positional encodings, and stacked attention and feed-forward blocks. In other cases, a latent transformer may operate directly on latent space vectors without relying on embeddings or positional encodings. The latent transformer may be better suited for modeling compressed data where relative sequence position is not essential. Either approach may be used to perform training and inference on encrypted or partially encrypted inputs, and may generate codeword-level or modality-specific outputs depending on system configuration.

Application Ser. No. 19/017,639 further describes a federated learning architecture in which a central coordinator manages distributed training across multiple edge devices. Each device may maintain its own local dataset and perform compression and encryption operations before contributing model updates to the global model. These updates may be aggregated at a central server using privacy-preserving protocols. The system may include mechanisms for enforcing differential privacy, such as the addition of calibrated noise and the use of per-device privacy budgets. It may also support distributed codebook management, allowing new entries to be proposed, validated, and disseminated across the network in a privacy-aware manner.

Application Ser. No. 19/242,953 introduces a hierarchical smart caching system that may be integrated into the codeword-based learning architecture. In this system, each edge device maintains a local cache divided into short-term and persistent tiers. These caches may store previously generated codeword responses, along with prompt context metadata, usage statistics, and relevance scores. A global cache may also be maintained to facilitate cross-device knowledge sharing and may include domain-specific partitioning, semantic indexing, and access controls. Cached responses may be evaluated using utility models that consider access frequency, model cost, and semantic proximity. When a new prompt is received, the system may consult the cache before initiating a full forward pass through the learning model, thereby reducing redundant computation.

The caching architecture may include components for resolving conflicts between cached responses, deduplicating semantically equivalent outputs, and tracking the evolution of entries across nodes. Synchronization protocols may be employed to update cache contents across devices, and privacy mechanisms may be used to enforce k-anonymity and prevent the inference of user-specific patterns from access statistics. Shared content may be anonymized, filtered, or selectively excluded from synchronization operations based on configurable policy constraints.

These architectural elements collectively define a scalable and privacy-aware platform for performing distributed learning on compressed and encrypted representations. The present application further describes techniques that may operate in conjunction with this architecture to enable adaptive synchronization of cached responses across federated environments. These techniques support selective sharing based on privacy requirements, model utility, and dynamic network conditions, thereby improving the efficiency of distributed caching while maintaining strong privacy guarantees.

### Conceptual Architecture of a Cache Synchronization System for Federated Large Codeword Models

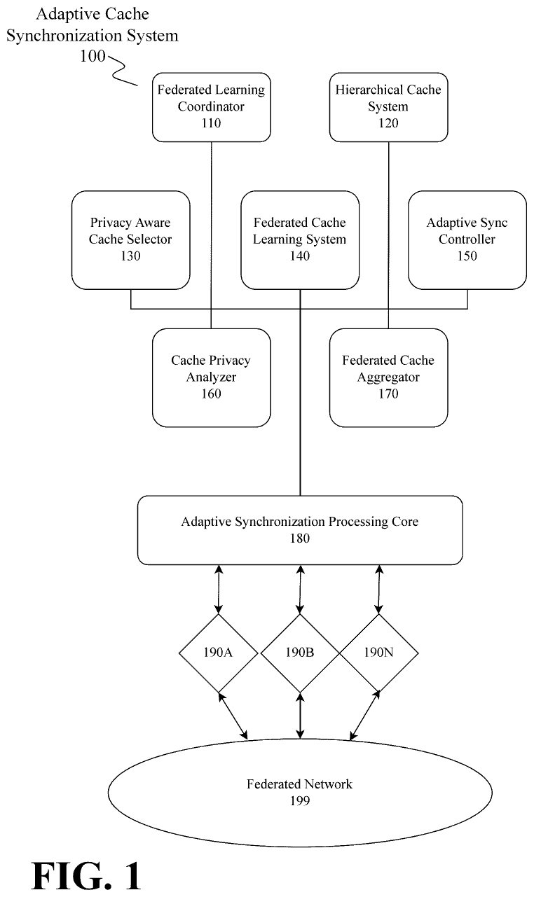

FIG. 1 is a block diagram illustrating exemplary architecture of an adaptive cache synchronization system 100, in an embodiment. Adaptive cache synchronization system 100 enables selective, privacy-conscious synchronization of cached model responses across a federated learning environment. The system is modular in nature, allowing components to be implemented, deployed, or updated independently based on architectural constraints, privacy requirements, or application-specific demands. The architecture integrates federated learning components 110 and hierarchical cache components 120, along with cache-aware privacy, learning, synchronization, and aggregation subsystems 130 through 170. A central processing core 180 coordinates these components and interfaces with edge devices 190A through 190N across a federated network 199.

Federated learning components 110 facilitate distributed training and inference across edge devices without requiring centralized access to raw input data. These components support encrypted or compressed codeword-based data exchanges and enable collaborative model refinement through techniques such as model aggregation and secure codebook sharing. In an embodiment, these components include a secure codebook manager and a model aggregator configured to process encrypted updates from distributed nodes.

Hierarchical cache components 120 provide memory structures for storing and retrieving previously generated model responses. These components include a local cache associated with each edge device and a global cache accessible across multiple devices. The local cache retains recently or frequently used responses, while the global cache aggregates entries considered broadly useful, such as generalized outputs or responses tied to common prompts.

Privacy-aware cache selector 130 determines whether and how each cached response should be shared with other nodes in the federated system. This component performs automated classification of cache entries using contextual metadata, prompt attributes, and response features, which may include token-level entropy, semantic generality, or user-specific markers. In an embodiment, privacy-aware cache selector 130 may assign a privacy score to each response using a rules-based engine or a trained classification model that evaluates characteristics such as input modality, inclusion of named entities, or response length. For example, a response may be labeled public if it contains only generalized or template-based content, such as a frequently asked question with a standard answer. A group-private label may be assigned to entries generated in a particular organizational unit or geographic region, and access to such entries may be restricted to nodes sharing the same group key or authorization profile. Fully-private entries may include references to personal data, unique identifiers, or rare prompts and may be excluded from all synchronization activities. In some embodiments, privacy-aware cache selector 130 may operate in tandem with cache privacy analyzer 160 to enforce tier-specific handling policies and reevaluate privacy designations over time based on access patterns or policy updates.

Federated cache learning system 140 analyzes cache access patterns and usage data collected from a plurality of distributed nodes to guide local and global cache policy decisions. This component aggregates statistical indicators such as cache hit and miss ratios, prompt frequency distributions, temporal access variance, and cache entry lifespan to determine which responses are most likely to benefit from replication across the network. In an embodiment, federated cache learning system 140 may train one or more machine learning models, such as decision trees, random forests, or neural networks, to estimate the utility of a cached response as a function of its content features and access history. For example, the model may learn that certain prompt structures—such as factual questions about system status—have high reuse across nodes, while personalized prompts do not. Training may occur periodically using federated learning techniques that allow edge devices to compute local gradients or parameter updates without revealing underlying response content. In some embodiments, training data may include feature vectors derived from cache metadata, augmented with usage statistics obfuscated through differential privacy noise injection. The resulting optimization model may be distributed to participating devices to guide retention decisions, synchronization eligibility, or local eviction policies.

Adaptive synchronization controller 150 schedules, initiates, and prioritizes cache synchronization operations across the federated system based on a range of runtime conditions. This component evaluates real-time system metrics including available network bandwidth, synchronization backlogs, cache utilization thresholds, privacy budget status, and observed request frequency for cached responses. In an embodiment, adaptive synchronization controller 150 may implement a scoring mechanism that ranks cache entries based on predicted reuse value, synchronization cost, and privacy classification, and selects entries that maximize benefit within current constraints. The controller may further adjust synchronization cadence dynamically in response to fluctuating network conditions or model drift indicators. For example, synchronization operations may be suppressed during high-traffic periods or deferred when a device's privacy budget has been nearly exhausted. In some embodiments, adaptive synchronization controller 150 includes a delta synchronization engine that performs data differencing on cache entries and transmits only incremental changes, such as modifications to response content, metadata updates, or version tags, thereby reducing bandwidth consumption in constrained environments.

Cache privacy analyzer 160 enforces user privacy constraints related to cache access, sharing activities, and policy compliance across the distributed system. This component monitors cache operations against a privacy budget, which may be a numerical representation of allowable information exposure for each node, user, or session. In an embodiment, the privacy budget is decremented based on the sensitivity and frequency of shared responses, and once a threshold is reached, the analyzer may halt further synchronization until the budget resets. Cache privacy analyzer 160 may also evaluate the risk of re-identification or leakage by analyzing response entropy, prompt uniqueness, or recipient overlap. For example, the analyzer may block sharing of a response unless it has been independently generated by at least k users, enforcing a k-anonymity requirement. In some embodiments, the analyzer may inject randomized noise into cache access statistics using differential privacy algorithms, or redact identifying entities from cached content using natural language processing techniques. These measures allow the system to balance cache efficiency with privacy preservation across diverse deployment environments.

Federated cache aggregator 170 manages the collection, resolution, and dissemination of cache entries across participating devices in the federated network. This component maintains a global index of shared responses using semantic identifiers, hash functions, or learned embeddings that associate similar entries generated under different conditions. When multiple devices produce similar but non-identical responses to equivalent prompts, federated cache aggregator 170 may perform semantic deduplication using embedding similarity, clustering algorithms, or language model scoring to select a representative version for distribution. In an embodiment, the aggregator maintains a distributed hash table to support efficient lookup, version tracking, and replication coordination. Version control mechanisms may include version vectors, timestamp-based precedence, or cryptographic digests to prevent conflicts and ensure consistency across nodes. The aggregator may also enforce network-wide resource quotas to prevent cache flooding by high-volume nodes and may prioritize replication based on device role, request rate, or geographic relevance.

Central processing core 180 coordinates the operation of components 130 through 170 and serves as the orchestration layer for adaptive cache synchronization system 100. This core manages synchronization commands, cache classification logic, privacy enforcement status, and dissemination of optimization models to edge devices 190A through 190C. In some embodiments, central processing core 180 may implement a policy engine that evaluates global system state, such as synchronization backlog depth, cache entry reuse rates, and aggregate privacy budget depletion, to trigger adaptive synchronization rounds or model retraining events. The core may further serve as an integration point for system logging, audit tracking, and anomaly detection, enabling administrative oversight of cache-related behavior across the network. Depending on deployment requirements, central processing core 180 may be implemented as a centralized service, a distributed cluster, or an orchestrated set of containers hosted in a cloud or edge infrastructure, based on system-wide utility forecasts or observed drift in model performance.

Edge devices 190A, 190B, and 190N represent participating nodes in the federated environment. Each device generates model outputs based on compressed or encrypted representations received from local input pipelines, and caches selected outputs for local reuse. Edge devices may receive cache policy models and synchronization instructions from central processing core 180 and may contribute anonymized usage data back to federated cache learning system 140.

Federated network 199 provides the communication infrastructure for synchronization, model update transmission, and cache coordination. This network supports secure data exchange between edge devices and central system components and may include encrypted channels, authenticated endpoints, or region-specific routing policies. Communication through federated network 199 enables distributed devices to operate collaboratively without revealing sensitive local data.

Together, components of adaptive cache synchronization system 100 enable responsive and efficient cache sharing across a privacy-sensitive, federated computing environment. The architecture supports selective synchronization of high-value cached responses while enforcing privacy constraints, optimizing for reuse potential, and adapting to environmental conditions such as bandwidth limitations and cache pressure. Components of adaptive cache synchronization system 100 may be implemented as distributed processes across multiple physical or virtual devices, or co-located within a single computing environment, depending on deployment requirements and resource constraints.

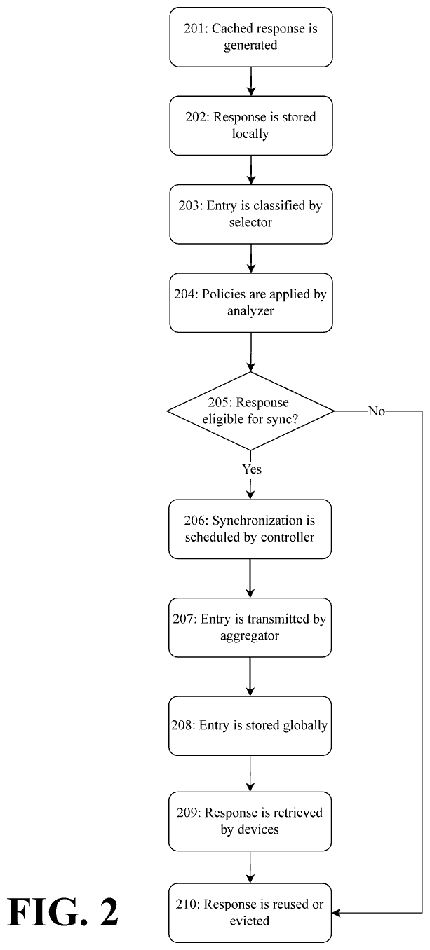

FIG. 2 is a flow diagram illustrating exemplary cache synchronization lifecycle of an adaptive cache synchronization system for federated large codeword models 100, in an embodiment. The process begins when a model executing on an edge device generates a response to an input, where the input has been transformed into a codeword-derived representation through a compression and transformation pipeline 201. The generated response is stored in a local cache associated with the edge device for potential future reuse, along with any accompanying metadata describing its origin, prompt context, or output structure 202.

The cached response is then evaluated by a privacy-aware cache selector 130, which analyzes the content and contextual information to assign a privacy classification based on system policies and configuration 203. A cache privacy analyzer 160 applies additional privacy enforcement measures, which may include differential privacy, anonymization, or k-anonymity constraints, to determine whether the entry can be shared beyond the local device 204. The system then determines whether the cached response is eligible for synchronization, based on its privacy tier, reuse potential, and current privacy budget status 205.

If the entry is eligible, an adaptive synchronization controller 150 schedules a synchronization operation, taking into account network conditions, bandwidth availability, and other synchronization priorities 206. The selected cache entry is transmitted across the federated network 199 via a federated cache aggregator 170, which manages delivery to other authorized nodes and performs consistency checks and deduplication as needed 207. The synchronized entry is stored in a global cache maintained within hierarchical cache components 120, where it becomes available to other participating devices 208.

An edge device receiving the synchronized entry may retrieve the cached response and determine, based on prompt similarity or other relevance criteria, whether the response is suitable for reuse without full model inference 209. Once reused or expired based on policy or age, the cached response may be evicted, retained, or updated as part of ongoing cache management operations 210.

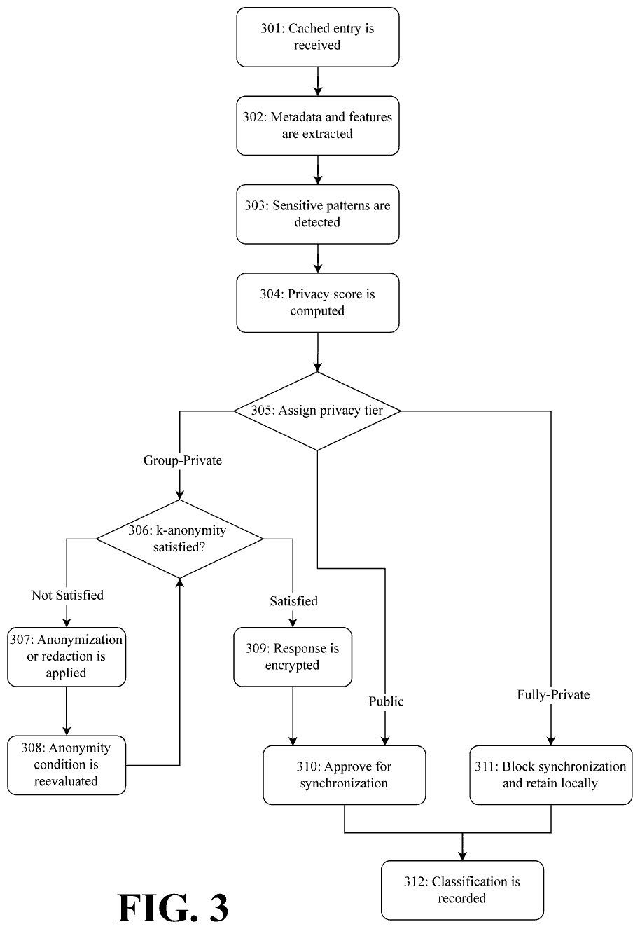

FIG. 3 is a flow diagram illustrating exemplary privacy-aware cache selection and classification of an adaptive cache synchronization system for federated large codeword models 100, in an embodiment. A cached entry is received for evaluation by privacy-aware cache selector 130 301.

Metadata and content features of the entry are extracted for analysis by privacy-aware cache selector 130 302.

Sensitive entities or patterns are detected within the entry by cache privacy analyzer 160 303. A privacy score is computed using classification logic within privacy-aware cache selector 130 304.

A privacy tier is assigned to the cached entry by privacy-aware cache selector 130, which may include public, group-private, or fully-private classifications 305.

A k-anonymity check is performed by cache privacy analyzer 160 to confirm sufficient similarity among entries before synchronization 306.

Transformations such as anonymization or redaction are applied to the cached entry by cache privacy analyzer 160 when the anonymity requirement is not satisfied 307.

The k-anonymity condition is reevaluated by cache privacy analyzer 160 until compliance is achieved 308.

Encryption is applied to prepare group-private responses for distribution to authorized devices by privacy-aware cache selector 130 309.

Fully-private entries are blocked from synchronization and retained locally under the control of privacy-aware cache selector 130 310.

Eligible entries are approved for synchronization 311 and the classification outcome is recorded by privacy-aware cache selector 130 for subsequent use by adaptive synchronization controller 150 312.

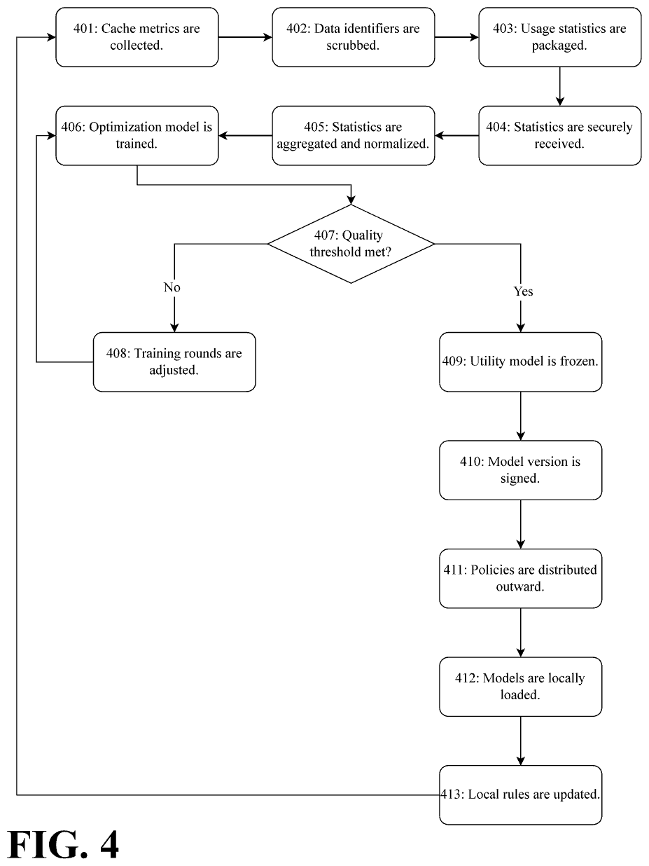

FIG. 4 is a flow diagram illustrating exemplary federated cache learning and optimization of an adaptive cache synchronization system for federated large codeword models 100, in an embodiment. The process begins at edge devices 190A-190N, where each device collects cache metrics such as hit and miss ratios, reuse frequency, and response age to characterize local cache behavior 401.

The edge devices then apply local differential privacy operations and identifier scrubbing so that no sensitive information is exposed in the statistics prepared for network transmission 402.

Each device packages these anonymized usage statistics into a format suitable for contribution to the federated cache learning system 140 403.

A federated cache learning system securely receives the anonymized statistics from multiple devices across the federated network 199 404.

A federated cache learning system aggregates and normalizes the received statistics to ensure consistency and comparability across heterogeneous sources 405.

A federated cache learning system trains a cache optimization model using a federated averaging process that incorporates the aggregated statistics without exposing underlying data 406.

A federated cache learning system evaluates whether the trained optimization model satisfies a quality threshold for prediction accuracy and generalization 407.

When the threshold is not met, a federated cache learning system adjusts training rounds or modifies hyperparameters and reinitiates the training process 408.

Once the threshold is achieved, a federated cache learning system freezes the cache utility model and the associated policy parameters for distribution 409.

A distribution and orchestration core 180 signs and versions the frozen model to maintain integrity and traceability 410.

A distribution and orchestration core then disseminates the signed model and policy parameters to the participating edge devices 411.

Each edge device loads the received model and policies into its local environment under direction of the distribution and orchestration core 180 412.

Finally, the edge devices update their local retention strategies, eviction policies, and synchronization eligibility rules according to the new optimization model, after which updated metrics flow back into the collection process, thereby completing the feedback loop of the adaptive cache synchronization system 413.

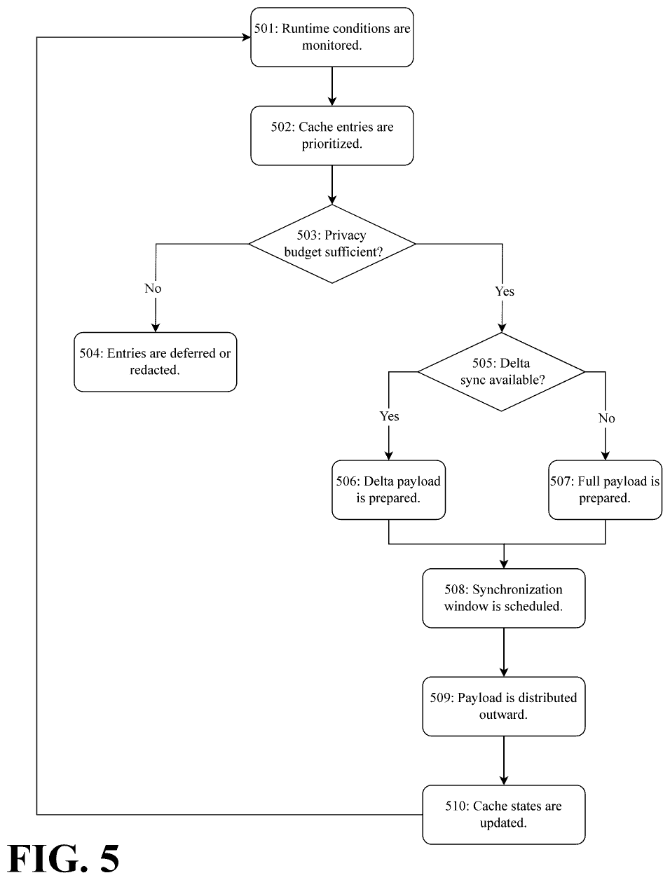

FIG. 5 is a flow diagram illustrating exemplary adaptive synchronization scheduling of an adaptive cache synchronization system for federated large codeword models 100, in an embodiment. The process begins as network bandwidth, cache utilization, privacy budgets, and response utility values are monitored by the adaptive synchronization controller 150 501.

Candidate cache entries are scored and prioritized by the adaptive synchronization controller 150 according to predicted reuse value and system conditions 502.

A determination is made by the cache privacy analyzer 160 whether sufficient privacy budget remains for synchronization 503.

When the budget is insufficient, entries are deferred or redacted by the cache privacy analyzer 160 before proceeding 504.

When the budget is sufficient, the adaptive synchronization controller 150 determines whether delta synchronization is available for the selected entries 505.

If delta synchronization is available, a delta payload is prepared by the federated cache aggregator 170 506.

If delta synchronization is not available, a full payload is prepared by the federated cache aggregator 170 507.

A adaptive synchronization controller 150 schedules a synchronization window for transmitting the prepared payload 508.

A federated cache aggregator 170 distributes the payload to authorized nodes across the federated network 199 509.

A receiving edge devices 190A-190N update their cache states based on the distributed payload, completing the synchronization cycle before returning to monitoring conditions 510.

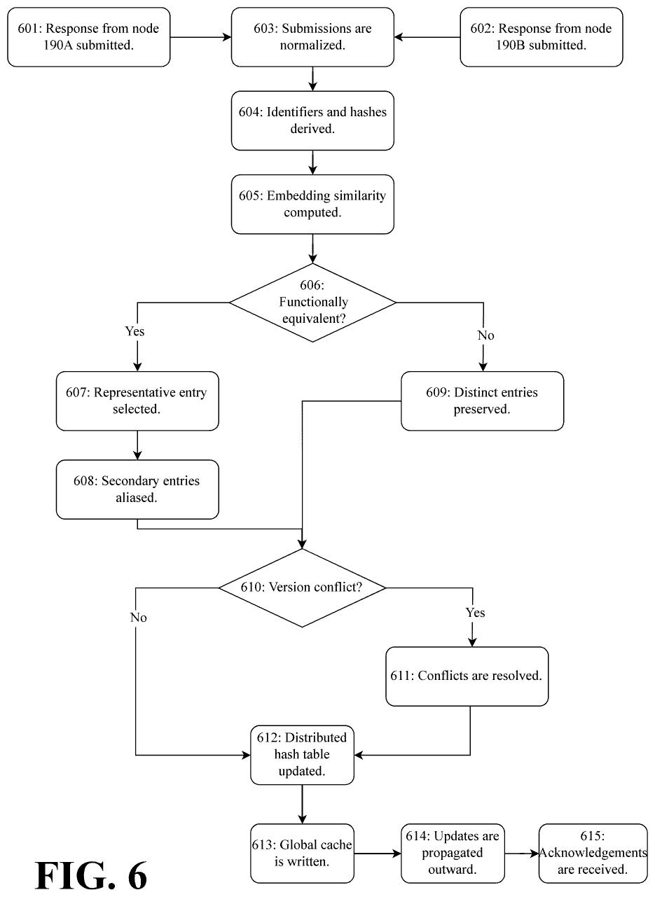

FIG. 6 is a flow diagram illustrating aggregator conflict resolution and deduplication of an adaptive cache synchronization system for federated large codeword models 100, in an embodiment. Cached responses generated at edge device 190A are submitted to federated cache aggregator 170 for reconciliation 601.

Cached responses generated at edge device 190B are likewise submitted to federated cache aggregator 170 for reconciliation 602.

The incoming submissions are ingested and normalized by federated cache aggregator 170 to establish a common comparison basis 603.

Identifiers and content hashes are derived by federated cache aggregator 170 to establish deterministic fingerprints for candidate entries 604.

Embedding similarity is computed by federated cache aggregator 170 to measure semantic proximity between candidate entries 605.

Functional equivalence of candidate responses is determined by federated cache aggregator 170 based on similarity thresholds and context alignment 606.

When equivalence is detected, a single representative entry is selected by federated cache aggregator 170 to stand in for redundant variants 607.

Non-representative entries are aliased to the representative by federated cache aggregator 170 to preserve traceability without duplication 608.

When equivalence is not detected, distinct entries are preserved as separate artifacts by federated cache aggregator 170 609.

Potential version conflicts among related entries are evaluated by federated cache aggregator 170 to detect divergent updates 610.

Version conflicts are resolved using version vectors or timestamp precedence coordinated by federated cache aggregator 170 611.

The distributed hash table mapping semantic identifiers to cache entries is updated by federated cache aggregator 170 to reflect deduplication and resolution outcomes 612.

The global cache within hierarchical cache components 120 is written with the resolved entries by federated cache aggregator 170 to maintain a consistent network view 613.

Update notifications and payloads are propagated to authorized edge devices 190A-190N via federated cache aggregator 170 over federated network 199 614.

Acknowledgements are received and synchronization state is refreshed by federated cache aggregator 170 under oversight of central processing core 180 to complete the cycle 615.

### Exemplary Computing Environment

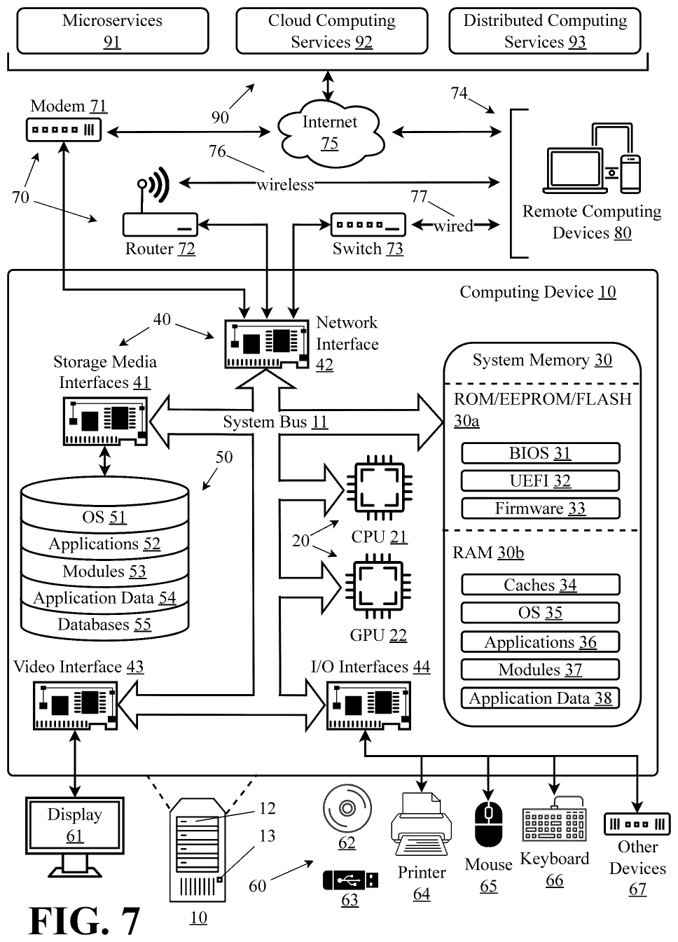

FIG. 7 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 12 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions based on technologies like complex instruction set computer (CISC) or reduced instruction set computer (RISC). Further, computing device 10 may comprise one or more specialized processors such as a graphics processing unit (GPU) 22 configured to accelerate processing of computer graphics and images via a large array of specialized processing cores arranged in parallel. Further computing device 10 may be comprised of one or more specialized processes such as Intelligent Processing Units, field-programmable gate arrays or application-specific integrated circuits for specific tasks or types of tasks. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed, and includes memory types such as read only memory (ROM), electronically-erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance. There are several types of computer memory, each with its own characteristics and use cases. System memory 30 may be configured in one or more of the several types described herein, including high bandwidth memory (HBM) and advanced packaging technologies like chip-on-wafer-on-substrate (CoWoS). Static random access memory (SRAM) provides fast, low-latency memory used for cache memory in processors, but is more expensive and consumes more power compared to dynamic random access memory (DRAM). SRAM retains data as long as power is supplied. DRAM is the main memory in most computer systems and is slower than SRAM but cheaper and more dense. DRAM requires periodic refresh to retain data. NAND flash is a type of non-volatile memory used for storage in solid state drives (SSDs) and mobile devices and provides high density and lower cost per bit compared to DRAM with the trade-off of slower write speeds and limited write endurance. HBM is an emerging memory technology that provides high bandwidth and low power consumption which stacks multiple DRAM dies vertically, connected by through-silicon vias (TSVs). HBM offers much higher bandwidth (up to 1 TB/s) compared to traditional DRAM and may be used in high-performance graphics cards, AI accelerators, and edge computing devices. Advanced packaging and CoWoS are technologies that enable the integration of multiple chips or dies into a single package. CoWoS is a 2.5D packaging technology that interconnects multiple dies side-by-side on a silicon interposer and allows for higher bandwidth, lower latency, and reduced power consumption compared to traditional PCB-based packaging. This technology enables the integration of heterogeneous dies (e.g., CPU, GPU, HBM) in a single package and may be used in high-performance computing, AI accelerators, and edge computing devices.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. In some high-performance computing systems, multiple GPUs may be connected using NVLink bridges, which provide high-bandwidth, low-latency interconnects between GPUs. NVLink bridges enable faster data transfer between GPUs, allowing for more efficient parallel processing and improved performance in applications such as machine learning, scientific simulations, and graphics rendering. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44. Network interface 42 may support various communication standards and protocols, such as Ethernet and Small Form-Factor Pluggable (SFP). Ethernet is a widely used wired networking technology that enables local area network (LAN) communication. Ethernet interfaces typically use RJ45 connectors and support data rates ranging from 10 Mbps to 100 Gbps, with common speeds being 100 Mbps, 1 Gbps, 10 Gbps, 25 Gbps, 40 Gbps, and 100 Gbps. Ethernet is known for its reliability, low latency, and cost-effectiveness, making it a popular choice for home, office, and data center networks. SFP is a compact, hot-pluggable transceiver used for both telecommunication and data communications applications. SFP interfaces provide a modular and flexible solution for connecting network devices, such as switches and routers, to fiber optic or copper networking cables. SFP transceivers support various data rates, ranging from 100 Mbps to 100 Gbps, and can be easily replaced or upgraded without the need to replace the entire network interface card. This modularity allows for network scalability and adaptability to different network requirements and fiber types, such as single-mode or multi-mode fiber.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid state memory technology. Non-volatile data storage devices 50 may be implemented using various technologies, including hard disk drives (HDDs) and solid-state drives (SSDs). HDDs use spinning magnetic platters and read/write heads to store and retrieve data, while SSDs use NAND flash memory. SSDs offer faster read/write speeds, lower latency, and better durability due to the lack of moving parts, while HDDs typically provide higher storage capacities and lower cost per gigabyte. NAND flash memory comes in different types, such as Single-Level Cell (SLC), Multi-Level Cell (MLC), Triple-Level Cell (TLC), and Quad-Level Cell (QLC), each with trade-offs between performance, endurance, and cost. Storage devices connect to the computing device 10 through various interfaces, such as SATA, NVMe, and PCIe. SATA is the traditional interface for HDDs and SATA SSDs, while NVMe (Non-Volatile Memory Express) is a newer, high-performance protocol designed for SSDs connected via PCIe. PCIe SSDs offer the highest performance due to the direct connection to the PCIe bus, bypassing the limitations of the SATA interface. Other storage form factors include M.2 SSDs, which are compact storage devices that connect directly to the motherboard using the M.2 slot, supporting both SATA and NVMe interfaces. Additionally, technologies like Intel Optane memory combine 3D XPoint technology with NAND flash to provide high-performance storage and caching solutions. Non-volatile data storage devices 50 may be non-removable from computing device 10, as in the case of internal hard drives, removable from computing device 10, as in the case of external USB hard drives, or a combination thereof. However, computing devices will typically comprise one or more internal, non-removable hard drives using either magnetic disc or solid-state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, NoSQL databases, vector databases, knowledge graph databases, key-value databases, document oriented data stores, and graph databases.

Applications (also known as computer software or software applications) are sets of programming instructions designed to perform specific tasks or provide specific functionality on a computer or other computing devices. Applications are typically written in high-level programming languages such as C, C++, Scala, Erlang, GoLang, Java, Scala, Rust, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems facilitated by specifications such as containerd.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network or optical transmitters (e.g., lasers). Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers or networking functions may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices or intermediate networking equipment (e.g., for deep packet inspection).

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90. Also, certain processing subtasks may be sent to a microservice 91 for processing with the result being transmitted to computing device 10 for incorporation into a larger processing task. Infrastructure as Code (IaaC) tools like Terraform can be used to manage and provision computing resources across multiple cloud providers or hyperscalers. This allows for workload balancing based on factors such as cost, performance, and availability. For example, Terraform can be used to automatically provision and scale resources on AWS spot instances during periods of high demand, such as for surge rendering tasks, to take advantage of lower costs while maintaining the required performance levels. In the context of rendering, tools like Blender can be used for object rendering of specific elements, such as a car, bike, or house. These elements can be approximated and roughed in using techniques like bounding box approximation or low-poly modeling to reduce the computational resources required for initial rendering passes. The rendered elements can then be integrated into the larger scene or environment as needed, with the option to replace the approximated elements with higher-fidelity models as the rendering process progresses.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is containerd, which is widely used in software development and deployment. Containerization, particularly with open-source technologies like containerd and container orchestration systems like Kubernetes, is a common approach for deploying and managing applications. Containers are created from images, which are lightweight, standalone, and executable packages that include application code, libraries, dependencies, and runtime. Images are often built from a containerfile or similar, which contains instructions for assembling the image. Containerfiles are configuration files that specify how to build a container image. Systems like Kubernetes natively support containerd as a container runtime. They include commands for installing dependencies, copying files, setting environment variables, and defining runtime configurations. Container images can be stored in repositories, which can be public or private. Organizations often set up private registries for security and version control using tools such as Harbor, JFrog Artifactory and Bintray, GitLab Container Registry, or other container registries. Containers can communicate with each other and the external world through networking. Containerd provides a default network namespace, but can be used with custom network plugins. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, mainframe computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are serverless logic apps, microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, protobuffers, gRPC or message queues such as Kafka. Microservices 91 can be combined to perform more complex or distributed processing tasks. In an embodiment, Kubernetes clusters with containerized resources are used for operational packaging of system.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over public or private networks or the Internet on a subscription or alternative licensing basis, or consumption or ad-hoc marketplace basis, or combination thereof.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power or support for highly dynamic compute, transport or storage resource variance or uncertainty over time requiring scaling up and down of constituent system resources. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, NVLink or other GPU-to-GPU high bandwidth communications links and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A computer system comprising a hardware memory, wherein the computer system is configured to execute software instructions stored on nontransitory machine-readable storage media that:
receive, from a plurality of distributed nodes, a plurality of codeword-derived representations associated with input data processed through a compression and transformation pipeline;
process the codeword-derived representations through a machine learning model to generate one or more responses;
store the one or more responses in a hierarchical cache comprising a local cache associated with the computer system and a global cache distributed across multiple nodes;
evaluate the stored responses for potential sharing based on content characteristics, access patterns, and privacy classification;
determine, using a privacy-aware cache selector, a sharing eligibility level for each stored response based on a privacy policy and contextual metadata associated with the response;
aggregate usage statistics from a plurality of nodes into a federated cache learning system configured to compute one or more cache optimization models;
control synchronization of selected cache entries across nodes using an adaptive synchronization controller that dynamically adjusts timing, frequency, and scope of synchronization operations based on network conditions, utility metrics, and privacy budget consumption;
apply a privacy mechanism to shared responses, wherein the privacy mechanism comprises at least one of differential privacy, homomorphic encryption, or anonymization of identifying elements; and
distribute selected cache entries to one or more nodes using a federated cache aggregator that manages versioning, deduplication, and replication consistency across the global cache.

2. The computer system of claim 1, wherein the privacy-aware cache selector classifies responses into at least a public tier, a group-private tier, and a fully-private tier based on content analysis and contextual metadata.

3. The computer system of claim 2, wherein group-private responses are encrypted using homomorphic encryption prior to distribution to a set of authorized nodes.

4. The computer system of claim 1, wherein the federated cache learning system applies a federated averaging algorithm to derive cache optimization models based on anonymized cache usage statistics received from multiple nodes.

5. The computer system of claim 1, wherein the adaptive synchronization controller implements delta synchronization by transmitting only changed portions of cache entries.

6. The computer system of claim 1, wherein the privacy mechanism comprises a differential privacy engine that adds calibrated noise to cache access metrics before aggregation.

7. The computer system of claim 1, wherein the privacy mechanism enforces k-anonymity by permitting synchronization only when a cached response is associated with at least k distinct users.

8. The computer system of claim 1, wherein the federated cache aggregator maintains a distributed hash table that maps semantic identifiers to cached responses across participating nodes.

9. The computer system of claim 1, wherein the federated cache aggregator performs semantic deduplication to identify functionally equivalent responses based on vector similarity or prompt context alignment.

10. A method for adaptive cache synchronization in a distributed machine learning environment, the method comprising:
receiving, at a computer system, a plurality of codeword-derived representations from a plurality of distributed nodes;
processing the codeword-derived representations using a machine learning model to generate one or more responses;
storing the one or more responses in a hierarchical cache comprising a local cache and a global cache distributed across the nodes;
evaluating the stored responses for potential sharing based on content characteristics, access patterns, and privacy classification;
determining, using a privacy-aware cache selector, a sharing eligibility level for each stored response based on a privacy policy and contextual metadata;
aggregating usage statistics from the distributed nodes into a federated cache learning system to compute one or more cache optimization models;
controlling synchronization of selected cache entries using an adaptive synchronization controller that adjusts timing, frequency, and scope of synchronization based on network conditions, utility metrics, and privacy budget consumption;
applying a privacy mechanism to shared responses, the privacy mechanism comprising at least one of differential privacy, homomorphic encryption, or anonymization of identifying elements; and
distributing selected cache entries to one or more nodes using a federated cache aggregator that manages versioning, deduplication, and replication consistency.

11. The method of claim 10, wherein the privacy-aware cache selector classifies the responses into a public tier, a group-private tier, and a fully-private tier.

12. The method of claim 11, further comprising encrypting group-private responses using homomorphic encryption prior to distribution to authorized nodes.

13. The method of claim 10, wherein computing the one or more cache optimization models comprises applying a federated averaging algorithm to anonymized cache usage statistics collected from the nodes.

14. The method of claim 10, wherein controlling synchronization further comprises performing delta synchronization by transmitting only changed portions of cache entries.

15. The method of claim 10, wherein applying the privacy mechanism comprises injecting calibrated noise into cache access metrics before aggregation.

16. The method of claim 10, wherein applying the privacy mechanism further comprises enforcing k-anonymity by permitting synchronization only when the associated response corresponds to at least k distinct users.

17. The method of claim 10, wherein distributing selected cache entries further comprises identifying cache entries using a distributed hash table that maps semantic identifiers to stored responses.

18. The method of claim 10, wherein distributing selected cache entries further comprises performing semantic deduplication to identify functionally equivalent responses based on vector similarity or prompt context alignment.
